(19) United States
(12) Patent Application Publication
(10) Pub. No.: US 2016/0035786 A1
(43) Pub. Date: Feb. 4, 2016

(54) METHOD OF FABRICATING A SEMICONDUCTOR DEVICE

(71) Applicant: KABUSHIKI KAISHA TOSHIBA, Tokyo (JP)

(72) Inventor: Tsuyoshi MATSUMURA, Oita Oita (JP)

(21) Appl. No.: 14/548,615

(22) Filed: Nov. 20, 2014

(30) Foreign Application Priority Data
Apr. 24, 2014 (JP) 2014-090743

(51) Int. Cl. H01L 27/146; H01L 21/306; H01L 21/304

(52) U.S. Cl. CPC H01L 27/14689; H01L 27/14612; H01L 27/14621; H01L 27/14627; H01L 27/14636; H01L 27/14643; H01L 27/14685; H01L 21/304; H01L 21/30625; H01L 21/30604

(57) ABSTRACT

There is provided a method of fabricating a semiconductor device, including grinding a first surface of a first semiconductor layer to generate a damage layer in a surface region of the first surface of the first semiconductor layer, polishing the damage layer to remove a portion with predetermined thickness of the damage layer; and etching the damage layer and the first semiconductor layer to remove the first semiconductor layer from a third surface of a second semiconductor layer, the third surface contacting to a second surface opposed to the first surface in the first semiconductor layer.

### CROSS REFERENCE TO RELATED APPLICATION

This application is based upon and claims the benefit of priority from prior Japanese Patent Application No. 2014-090743, filed on Apr. 24, 2014, the entire contents of which are incorporated herein by reference.

### FIELD

Exemplary embodiments described herein generally relate to a method of fabricating a semiconductor device.

### BACKGROUND

An imaging device is used as an optical instrument such as a camera. The imaging device includes photo diodes each of which performing photoelectric conversion, transistors each of which is used for reading, and wiring layers. A back-illumination imaging device, in which the photo diode receives light from an opposite side to the wiring layers, is one of the imaging devices.

In the back-illumination imaging device, the photo diode is provided above a surface of a semiconductor substrate in conjunction with the transistor, and the wiring layers are provided on the photo diode and the semiconductor substrate. Accordingly, the photo diode is supposed to receive light transmitting through a semiconductor substrate. In such a manner, the semiconductor substrate is necessary to be thinned or removed by etching so that the photo diode can sufficiently receive light.

A method described below is often used in etching the semiconductor substrate. In the method, etching is stopped at a desired depth due to resistivity difference originating from impurity concentration difference. In such the case, etching selectivity is important. The etching selectivity is a ratio of an etching rate of an etched layer to an etching rate of a stopping layer, which underlies the etched layer. The selective etching described above is used for not only a method of fabricating the imaging device but also that of fabricating a semiconductor device.

### BRIEF DESCRIPTION OF THE DRAWINGS

FIG. 1 is a cross-sectional view showing a method of fabricating an imaging device according to an embodiment;

FIG. 2 is a cross-sectional view showing the method of fabricating the imaging device according to the embodiment;

FIG. 3 is a cross-sectional view showing the method of fabricating the imaging device according to the embodiment;

FIG. 4 is a graph showing a relationship between an etching rate of silicon and an impurity concentrate in silicon according to the first embodiment;

FIG. 5A, 5B show surface roughness of semiconductor substrates on which a damage layer remains and on which a damage layer is etched by predetermined amount, respectively, after selective etching according to the embodiment; and

FIG. 6 is graph showing a range of a thickness of semiconductor substrate to be removed according to the embodiment.

### DETAILED DESCRIPTION

An aspect of one embodiment, there is provided a method of fabricating a semiconductor device, including grinding a first surface of a first semiconductor layer to generate a damage layer in a surface region of the first surface of the first semiconductor layer, polishing the damage layer to remove a portion with predetermined thickness of the damage layer, and etching the damage layer and the first semiconductor layer to remove the first semiconductor layer from a third surface of a second semiconductor layer, the third surface contacting to a second surface opposed to the first surface in the first semiconductor layer.

Embodiments will be described below in detail with reference to the attached drawings mentioned above. Throughout the attached drawings, similar or same reference numerals show similar, equivalent or same components, and the description is not repeated.

### First Embodiment

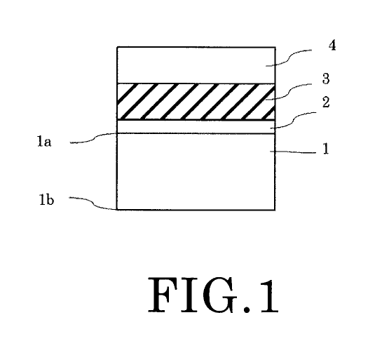

Processing steps of an imaging device in an embodiment are explained by using FIGS. 1-3. FIGS. 1-3 are cross-sectional views showing a part of processing steps of fabricating the imaging device, respectively, according to the embodiment. In this embodiment, the processing steps are described in a case where both of a semiconductor substrate and an epitaxial layer have a p-type as a conductive type. Similarly, the embodiments can be also carried out in the other case where both the semiconductor substrate and the epitaxial layer have an n-type as a conductive type. In this embodiment, a back-illumination imaging device is used as an example. However, it is not restricted to that type. Moreover, the approach described above can be applied to not only the imaging device but also a semiconductor device.

The imaging device fabricated by a method described in the embodiment includes an epitaxial layer having at least one of a photo diode, a transistor, a wiring layer, a color filter, a micro lens or the like.

As shown in FIG. 1, a semiconductor substrate 1 composed of silicon (Si) has a first surface 1a and a second surface 1b opposed to the first surface 1a. A semiconductor substrate 1 has p-type as a conductive type and is doped with boron. A boron concentration is, for example, 8.5×10¹⁸ cm⁻³.

An epitaxial layer 2 is provided on the first surface 1a of the semiconductor substrate 1 by chemical vapor deposition (CVD), for example. The photo diode, the transistor or the like (not shown) is provided on the epitaxial layer 2. The epitaxial layer 2 with a p-type as the conductive type has an impurity concentration of 1.6×10¹⁶ cm⁻³, for example.

A wiring layer 3 is provided on the epitaxial layer 2. The wiring layer 3 includes, for example, an insulating film such as a silicon dioxide film, and a copper wiring (not shown), for example, formed in the insulating film by Dual Damascene. Light enters into the photo diode which performs photoelectric conversion to the entered light. Electrons generated by the photoelectric conversion are outputted into an outer circuit via the transistor, the wiring layer 3 and the like.

A supporting substrate 4 is stuck with the wiring layer 3 to be provided on the wiring layer 3.

The supporting substrate 4 acts as a supporting material to retain strength of the semiconductor substrate 1 when the semiconductor substrate 1 is polished to be thinned,

After sticking the supporting substrate 4 on the wiring layer 3, the semiconductor substrate 1 is thinned or removed. The color filter and the micro lens are provided and the fabrication of the imaging device is completed.

In this embodiment, a damage layer 5 is formed on the second surface 1b of the semiconductor substrate 1 before the semiconductor substrate 1 is thinned or removed by etching. In such a manner, reaction rate of the etching can be higher without lowering a selective etching ratio during the etching.

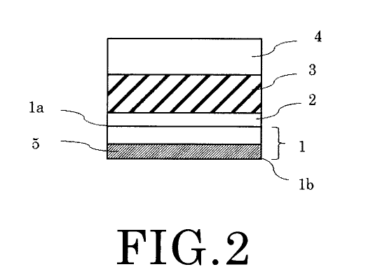

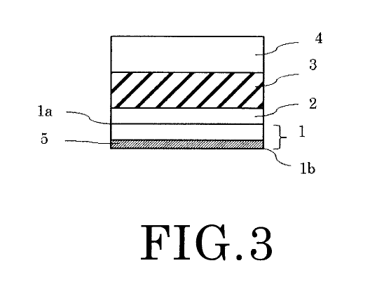

Description on the processing steps mentioned above is described below using FIGS. 2, 3.

As shown in FIG. 2, the semiconductor substrate 1 is mechanically winded from a side of the second surface 1b to be thinned to a thickness of nearly 6 μm, for example. As a result, the second surface 1b is roughened. As shown in FIG. 2, the roughened surface penetrates from the second surface 1b into the semiconductor substrate 1 with an area. The roughened area is a damage layer 5. The damage layer 5 includes strained crystal with crystal defects and has a thickness of nearly 3 μm, for example. Granularity of a polishing material used in the mechanical grinding is #370-2000, for example, in Japanese Industrial Standard.

As shown in FIG. 3, the damage layer 5 is polished by chemical mechanical polishing (CMP) to be removed with a predetermined thickness. A portion of the surface side, which is also the second surface 1b of the semiconductor substrate 1, of the damage layer 5 is removed such that the other portion of the damage layer 5 is remained.

Next, the semiconductor substrate 1 is etched.

As an etching solution, which is a mixed solution including hydrofluoric acid (HF), nitric acid (HNO₃) and acetic acid (CH₃COOH), or the like can be used. The etching solution performs etching of the semiconductor substrate 1 composed of Si to generate nitrous acid. Nitrous acid oxidizes Si to transform into silicon dioxide so that hydrofluoric acid dissolves silicon dioxide such that the etching solution can etch Si. In the etching process, the second surface 1b of the semiconductor substrate 1 is etched. The epitaxial layer 2 with lower impurity concentration acts as an etching stop layer.

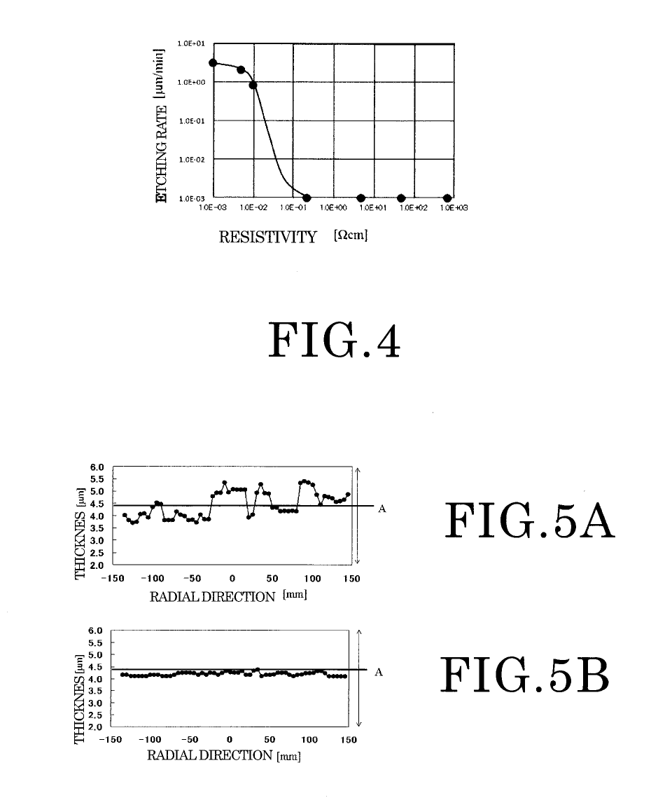

Here, selective etching of the semiconductor substrate 1 is explained in detail. FIG. 4 shows a relationship between an etching rate of Si and an impurity concentration. In the graph, results of the semiconductor substrate 1 and the epitaxial layer 2 etched by the etching solution is demonstrated. X-axis and Y-axis show resistivity and etching rate, respectively. Resistivity is dependent on impurity concentration. When the impurity concentration is higher, the resistivity is lower. On the contrary, when the impurity concentration is lower, the resistivity is higher. A boron concentration of the semiconductor substrate 1 is 8.5×10¹⁸ cm⁻³ and is higher than that of the epitaxial layer 2 having the concentration of 1.6×10¹⁶ cm⁻³. Therefore, the semiconductor substrate 1 with comparatively low resistivity has higher etching rate, on the contrary, the epitaxial layer 2 with comparatively high resistivity has lower etching rate. Accordingly, the epitaxial layer 2 is scarcely etched when the resistivity of the epitaxial layer 2 is not less than nearly 0.1 Ωcm as shown in FIG. 4. In such a manner, the semiconductor substrate 1 is selectively etched to the epitaxial layer 2 owing to the impurity concentration difference. An approach to selective etching by resistivity difference as another case is a method using silicon and poly crystalline silicon, for example.

However, etching of the semiconductor substrate 1 cannot be easily started, when the damage layer 5 is polished by CMP to be completely removed so that the semiconductor substrate 1 is flattened. Conventionally, the flattened semiconductor substrate 1 is etched with increasing etching rate by changing a ratio between chemical solutions in such the case. When changing the ratio between chemical solutions, both the etching rate of the semiconductor substrate 1 and that of the epitaxial layer 2, which acts as the etching stop layer, are increased. As a result, a ratio of the etching rate of the semiconductor substrate 1 to that of the epitaxial layer 2 is decreased to have less performance on the selectivity between the etching rate of the semiconductor substrate 1 and that of the epitaxial layer 2. Accordingly, the selective etching of the semiconductor substrate 1 to the epitaxial layer 2 becomes difficult,

In the embodiment, the second surface 1b of the semiconductor substrate 1 mechanically grinded so that the damage layer 5 on the semiconductor substrate 1 is remained. In such a state, the semiconductor substrate 1 is etched. As a result, nitrous acid included in the etching solution is inserted into crystalline defects in the damage layer 5 to enhance the oxidation of the semiconductor substrate 1, namely Si. The silicon dioxide is dissolved by hydrofluoric acid to enhance the etching of Si. Accordingly, the etching of the semiconductor substrate 1 can be started without increasing the etching rate by changing the ratio between the solutions in the mixed solution. The semiconductor substrate 1 can be selectively etched without decreasing of the etching ratio.

FIG. 5A show on a roughness of the surface of the semiconductor substrate 1 after etching from the semiconductor substrate 1 to the epitaxial layer 2 with the damage layer remained on the surface of the semiconductor substrate. FIG. 5B shows a roughness of the surface of the epitaxial layer 2 after etching from the semiconductor substrate 1 to the epitaxial layer 2 with the damage layer removed by predetermined thickness.

In FIGS. 5A, 5B, X-axis shows a position in a radial direction of the semiconductor substrate 1 and Y-axis shows a thickness which is sum of the thickness of the epitaxial layer 2 and the thickness of the semiconductor substrate 1 in a direction from an interface between the wiring layer 3 and the epitaxial layer 2 to the semiconductor substrate 1. Line A in FIGS. 5A, 5B shows an interface between the semiconductor substrate 1 and the epitaxial layer 2. The thickness of the epitaxial layer 2 in the embodiment, for example, is set to be 4.4 μm. An upper portion over 4.4 μm in Y-axis is an area of the semiconductor substrate 1.

As shown in FIG. 5A, when a portion from the semiconductor substrate 1 to the epitaxial layer 2 is etched without removing the predetermined thickness of the damage layer 5 from the surface, the surface of the epitaxial layer 2 is not flattened to include concave and convex on the surface. On the other hand, as shown in FIG. 5B, when the predetermined thickness of the damage layer 5 from the surface is removed, the surface of epitaxial layer 2 after etching from the semiconductor substrate 1 to the epitaxial layer 2 is flattened to decrease concave and convex on the surface as compared to the surface of the epitaxial layer 2 in FIG. 5A. In such a manner, the surface flatness of the epitaxial layer 2 after etching from the semiconductor substrate 1 to the epitaxial layer 2 can be improved when the predetermined thickness of the damage layer 5 is removed.

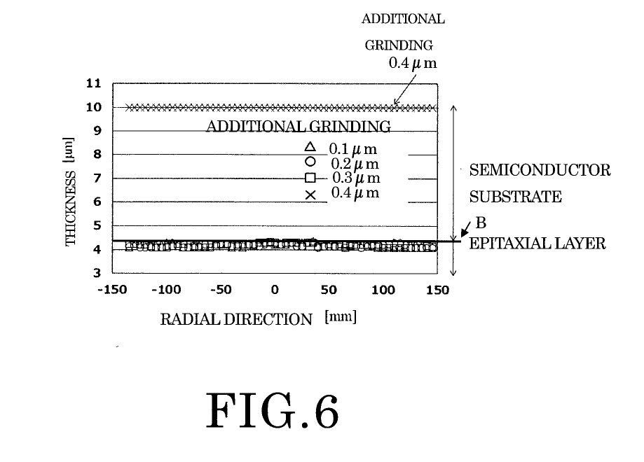

A range of the thickness of the removed portion in the damage layer 5 is concretely described in FIG. 6 such that the surface of the epitaxial layer 2 can be flattened as mentioned above.

In FIG. 6, X-axis shows a position in the radial direction of the semiconductor substrate 1 and Y-axis shows a thickness which is sum of the thickness of the epitaxial layer 2 and the thickness of the semiconductor substrate 1 in the direction from the interface between the wiring layer 3 and the epitaxial layer 2 to the semiconductor substrate 1. Line B in FIG. 6 shows the interface between the semiconductor substrate 1 and the epitaxial layer 2.

As shown in FIG. 6, when the predetermined thickness of the damage layer 5 to be removed is 0.1 μm, 0.2 μm and 0.3 μm, the semiconductor substrate 1 is selectively etched to the epitaxial layer 2 to flatten the surface of the epitaxial layer 2 after the etching.

The semiconductor substrate 1 can be etched to flatten the surface of the epitaxial layer 2 after the etching, when the thickness of the damage layer 5 to be removed is at least not less than 0.1 μm.

When the thickness of the damage layer 5 to be removed is not less than 0.4 μm, the semiconductor substrate 1 is remained on the epitaxial layer 2 and the etching of Si is inhibited. It is because that a density of the crystalline defects in the damage layer 5 after grinding decreases from the surface to the inner region. When the thickness of the damage layer 5 to be removed exceeds a constant value, the surface of the damage layer 5 is supposed not to include sufficient density of the crystalline defects for the etching. In the embodiment, the thickness of the damage layer 5 to be removed by CMF is designed to be not more than 0.3 μm. Accordingly, the semiconductor substrate 1 is easily reacted with the etching solution via the crystalline defects in the damage layer 5 as described above so that the etching of the semiconductor substrate 1 can be started. The etching rate is not necessary to be increased due to the ratio between the chemical solutions in the etching solution. The semiconductor substrate 1 can be selectively removed with retaining the selective etching ratio between the semiconductor substrate 1 and the epitaxial layer 2. The flatness of the surface of the epitaxial layer 2 after etching is obtained when the thickness of the damage layer 5 to be removed is set to not less than 0.1 μm.

The semiconductor substrate 1 can be selectively etched to retain the thickness of the epitaxial layer 2 including the photo diode by using the processing steps described in the embodiment. The imaging device can be fabricated using conventional processes of the imaging device after the process in the embodiment.

The method of fabricating the imaging device is described in the embodiment. However, the embodiment is not restricted to image devices but can be applied to a method of fabricating other semiconductor device in which selective etching process is used.

While certain embodiments have been described, these embodiments have been presented by way of example only, and are not intended to limit the scope of the inventions. Indeed, the novel embodiments described herein may be embodied in a variety of other forms: furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of fabricating a semiconductor device, comprising:
grinding a first surface of a first semiconductor layer to generate a damage layer in a surface region of the first surface;
polishing the damage layer to remove a portion with predetermined thickness of the damage layer; and
etching the damage layer and the first semiconductor layer to remove the first semiconductor layer on a third surface of a second semiconductor layer, the third surface contacting to a second surface opposed to the first surface of the first semiconductor layer.

2. The method of claim 1, wherein
the predetermined thickness is not less than 0.1 μm and not more than 0.3 μm.

3. The method of claim 1, wherein
an impurity concentration of the first semiconductor layer is higher than an impurity concentration of the second semiconductor layer.

4. The method of claim 1, wherein
a fourth surface opposed to the third surface of the second semiconductor layer contacts to a fifth surface of a wiring layer.

5. The method of claim 1, wherein
the second semiconductor layer includes a photo diode and a transistor.

6. The method of claim 1, wherein
in the removing of the first semiconductor layer, the first semiconductor layer is etched by an etching solution composed of hydrofluoric acid, nitric acid and acetic acid.

7. The method of claim 1, wherein
resistivity of the first semiconductor layer is not less than 0.10 cm.

8. The method of claim 1, wherein
the first semiconductor layer is included in a semiconductor substrate.

9. The method of claim 1, wherein
the second semiconductor layer is an epitaxial layer.

10. The method of claim 1, further comprising:
providing the second semiconductor layer on the second surface of the first semiconductor layer, before grinding the first surface.

11. The method of claim 10, further comprising:
providing the photo diode and the transistor on the second semiconductor layer, after providing the second semiconductor layer and before grinding the first surface.

12. The method of claim 11, further comprising:
providing the wiring layer on a fourth surface opposed to the third surface of the second semiconductor layer, after providing the photo diode and the transistor on the second semiconductor layer and before grinding the first surface.

13. The method of claim 12, further comprising:
providing a supporting substrate on the wiring layer, after providing the wiring layer and before grinding the first surface.

14. The method of claim 13, further comprising:
providing a color filter on the second semiconductor layer, after removing the first semiconductor layer.

15. The method of claim 13, further comprising:
providing a micro lens on the second semiconductor layer, after removing the first semiconductor layer.
